(19) United States
(12) Patent Application Publication
(10) Pub. No.: US 2026/0276259 A1
(43) Pub. Date: Sep. 17, 2026

(54) SPATIO-THERMAL ENERGY MODULATION VESSEL WITH EMBEDDED CONDUCTIVE FRAMEWORK

(71) Applicant: FAIZAN AHMED, SAN JOSE, CA (US)

(72) Inventor: FAIZAN AHMED, SAN JOSE, CA (US)

(21) Appl. No.: 19/391,849

(22) Filed: Nov. 17, 2025

Related U.S. Application Data
(60) Provisional application No. 63/770,818, filed on Mar. 12, 2025.

(51) Int. Cl. F25B 21/02; H05K 7/20

(52) U.S. Cl. CPC F25B 21/02; H05K 7/20272; H05K 7/20281; F25B 2321/0211; F25B 2321/0252; F25B 2500/01; F25B 2700/2104

(57) ABSTRACT

The invention provides a portable temperature-controlled enclosure configured to maintain a stable temperature for sensitive payloads. The enclosure includes a thermally insulated housing defining an interior payload chamber and a thermoelectric-effect cooling assembly thermally coupled to the chamber through a thermal interface material applied at a controlled thickness and verified for full-surface coverage. A thermal control material is positioned adjacent to the payload chamber to provide passive thermal buffering and lateral heat spreading. A heat-exchange subsystem dissipates heat generated by the cooling assembly, while a rechargeable battery enables autonomous operation. A control system with one or more temperature sensors and associated electronics monitors internal conditions and regulates the thermoelectric-effect cooling assembly to maintain the payload chamber within a defined temperature range.

### CLAIM OF PRIORITY

This United States Patent Application claims priority to U.S. Provisional Patent Application No. 63/770,818, filed on March 12, 2025, and titled SPATIO-THERMAL ENERGY MODULATION VESSEL WITH EMBEDDED CONDUCTIVE FRAMEWORK. This provisional patent application is hereby incorporated by reference in its entirety.

### BACKGROUND

### Field of the Invention

### Field of the Invention

The present invention relates generally to portable temperature-controlled storage systems, and more particularly to an SPATIO-THERMAL ENERGY MODULATION VESSEL WITH EMBEDDED CONDUCTIVE FRAMEWORK.

### BACKGROUND

Temperature-sensitive materials used in medical, biological, and industrial applications require stable and precise temperature regulation during storage and transport to prevent degradation or loss of viability. Traditional portable cooling technologies rely on compressor systems, chemical refrigerants, or ice-based passive media, all of which introduce substantial limitations. Compressor systems consume significant power, generate mechanical vibration, and are generally too bulky for handheld or battery-powered use. Ice packs and similar passive cooling elements provide uncontrolled temperature curves, create uneven thermal profiles, and cannot maintain a defined temperature range once the ice transitions begins.

These limitations become more severe in use cases requiring extended autonomous operation without access to external power. Compressor-based systems cannot sustain long-duration cooling on battery power, while passive solutions have no ability to actively regulate temperature or compensate for changing ambient conditions. Systems relying solely on passive thermal control materials are unable to maintain a narrow temperature band over prolonged periods, particularly when subjected to variable or extreme environmental temperatures.

Existing portable cooling systems also commonly suffer from inefficient heat transfer between their cooling elements and payload chambers. Suboptimal thermal interfaces, undersized heat-spreading structures, and non-optimized geometries frequently lead to internal temperature gradients that compromise payload stability. These challenges are especially pronounced in compact form-factor devices, where limited internal volume restricts the use of traditional heat-exchange pathways and results in inconsistent temperature uniformity across the payload region.

### SUMMARY OF THE INVENTION

The invention provides a portable temperature-controlled enclosure designed to maintain a stable and precise internal temperature for sensitive payloads. The enclosure includes a thermally insulated housing that defines an interior payload chamber. A thermoelectric-effect cooling assembly is thermally coupled to the payload chamber through a thermal interface material that is applied at a controlled thickness and verified for full-surface coverage to ensure consistent heat transfer. A thermal control material is positioned adjacent to the payload chamber to provide passive thermal buffering and lateral heat spreading, thereby supporting uniform temperature distribution. The enclosure further incorporates a heat-exchange subsystem configured to dissipate heat generated by the thermoelectric-effect cooling assembly during operation. A power subsystem with a rechargeable battery enables autonomous operation without reliance on external power sources. A control system, which includes one or more temperature sensors and associated electronics, continuously monitors internal temperature conditions and regulates operation of the thermoelectric-effect cooling assembly to maintain the payload chamber within a defined temperature range.

### BRIEF DESCRIPTION OF THE DRAWINGS

FIG. 1 is a top view of example embodiment of a portable temperature-controlled enclosure, according to some embodiments.

FIGS. 2 and 3 are isometric views of example embodiment of a portable temperature-controlled enclosure, according to some embodiments.

FIG. 4 is a front view of example embodiment of a portable temperature-controlled enclosure, according to some embodiments.

FIG. 5 is a side view of example embodiment of a portable temperature-controlled enclosure, according to some embodiments.

FIG. 6-9 illustrate various example views of an aluminum cooling chamber portable unit, according to some embodiments.

FIG. 6 illustrates a top-view of aluminum cooling chamber portable unit, according to some embodiments.

FIG. 7 illustrates a isometric-view of aluminum cooling chamber portable unit, according to some embodiments.

FIG. 8 illustrates a rear-view of aluminum cooling chamber portable unit, according to some embodiments.

FIG. 9 illustrates a side-view of aluminum cooling chamber portable unit, according to some embodiments.

FIG. 10 is a block diagram of a sample computing environment that can be utilized to implement various embodiments.

FIG. 11 illustrates a logical view of a portable temperature-controlled enclosure, according to some embodiments.

FIG. 12 illustrates an exterior view of portable temperature-controlled enclosure having a rectangular insulated housing configured for top-loading operation, according to some embodiments.

FIG. 13 provides a top view of portable temperature-controlled enclosure, according to some embodiment.

FIG. 14 provides a front view of portable temperature-controlled enclosure, according to some embodiments.

FIG. 15 provides a side view of portable temperature-controlled enclosure, according to some embodiments.

The Figures described above are a representative set and are not an exhaustive with respect to embodying the invention.

### DESCRIPTION

Disclosed are a system, method, and article of manufacture for an advanced thermal management systems with cooling chamber. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown. Appendix A includes additional information for implementing various embodiments.

### Definitions

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Thermoelectric effect is the presence of heating or cooling at an electrified junction of two different conductors. When a current is made to flow through a junction between two conductors, A and B, heat may be generated or removed at the junction. Thermoelectric cooling uses the Thermoelectric effect to create a heat flux between the junction of two different types of materials. A Peltier cooler, heater, or thermoelectric heat pump is a solid-state active heat pump which transfers heat from one side of the device to the other, with consumption of electrical energy, depending on the direction of the current. Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

Thermal control material (TCM) can be any material configured to absorb, buffer, store, or redistribute thermal energy in order to moderate temperature variations within a controlled volume. A TCM can undergo sensible and/or latent heat exchange and can be implemented, for example, using phase change materials (TCM), paraffin or non-paraffin waxes, salt hydrates, eutectic formulations, gels, hydrocarbon-based compositions, or composite thermal masses. Heat can be absorbed or released by the TCM as it changes state or temperature, thereby providing thermal buffering and improved temperature stability in portable temperature-controlled systems.

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

### Example Smart Refrigerator Exterior Views

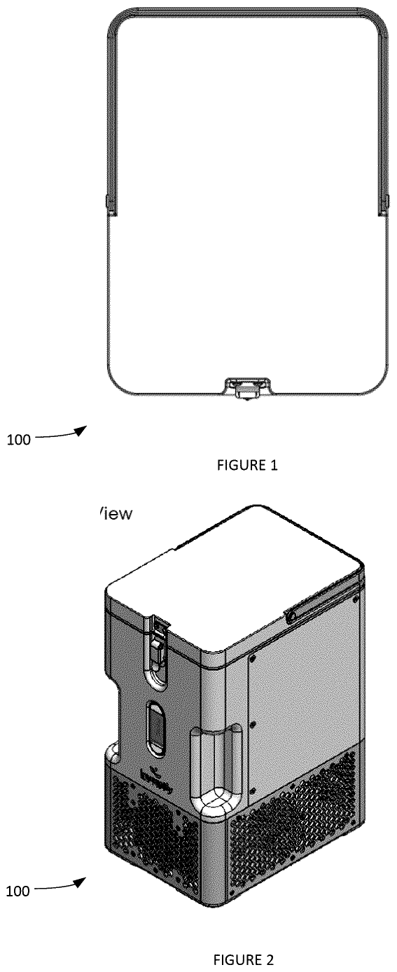

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a top loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with sophisticated control systems to achieve superior temperature stability and extended battery operation.

Portable temperature-controlled enclosure 100 comprises several key components working in concert: a precision-engineered payload chamber for storing temperature-sensitive materials, an optimized thermoelectric-effect cooling system with angular mounting configuration, an integrated thermal control material (TCM) chamber (e.g., containing one or more phase change materials (TCM) or other thermal buffering materials) for thermal energy buffering, and a sophisticated heat dissipation system including honeycomb ventilation. These components are managed by advanced monitoring and control systems, all supported by extended battery-powered operation capability.

The top-loading portable temperature-controlled enclosure 100 represents a breakthrough in portable refrigeration technology, utilizing solid-state cooling principles to maintain precise temperature control. The top-loading portable temperature-controlled enclosure 100 distinguishes itself through the complete elimination of traditional cooling infrastructure components such as compressors, refrigerant gases, cooling coils, ice packs, or gel packs.

Example physical specifications of the top-loading portable temperature-controlled enclosure 100 are now discussed. The top-loading portable temperature-controlled enclosure 100 payload capacity, by way of example, can be a one (1) liter. The top-loading portable temperature-controlled enclosure 100 can include a top-loading design with example dimensions of 107.78 mm×119.92 mm×166.84 mm.

Access to the top-loading portable temperature-controlled enclosure 100 can be via a top-mounted lid providing full access to internal chamber. Construction of The top-loading portable temperature-controlled enclosure 100 can include precision-engineered aluminum chamber with integrated cooling system.

An example Core Cooling Technology of the top-loading portable temperature-controlled enclosure 100 is now discussed. The top-loading portable temperature-controlled enclosure 100 employs an advanced solid-state cooling mechanism based on semiconductor physics. As a cooling principle, the top-loading portable temperature-controlled enclosure 100 utilizes an electron mobility differential between semiconductor materials. By way of operation, the top-loading portable temperature-controlled enclosure 100 uses an electric current passage through dual-semiconductor junction.

The thermal energy absorption during electron transition between materials is implemented to optimizes cooling efficiency. The top-loading portable temperature-controlled enclosure 100 can achieve target temperature (2° C.) within 2-hour initialization period. The top-loading portable temperature-controlled enclosure 100 implements temperature maintenance to maintain 2-8° C. range for 72 hours without external power.

An example Thermal Management System of the internal payload chamber incorporates a sophisticated thermal management design. As seen below, the top-loading portable temperature-controlled enclosure 100 includes a chamber construction that includes payload 104. Here, the material composition can include a specialized heat-absorbing material combined with aluminum. The top-loading portable temperature-controlled enclosure 100 utilizes thermal spreading via an engineered aluminum structure for optimal temperature distribution. The top-loading portable temperature-controlled enclosure 100 performs heat absorption via a material matrix for thermal energy management.

The top-loading portable temperature-controlled enclosure 100 provides dynamic temperature control. Primary cooling is performed via a solid-state thermoelectric-effect semiconductor chip (e.g., discussed infra). Supplementary cooling can be performed via a thermal control material (TCM) buffer system configured to absorb and release thermal energy to reduce temperature excursions within the payload chamber. Hybrid operation between TCM-based thermal mass buffering and active cooling response systems can be used for temperature maintenance, and automated cooling bursts can be executed to compensate for detected temperature deviations.

The top-loading portable temperature-controlled enclosure 100 can include a power and environmental adaptation power system 1102. The top-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the top-loading portable temperature-controlled enclosure 100 functions in extreme cold environments (−20° C. to −30° C.). Thermal management systems 1104 of the top-loading portable temperature-controlled enclosure 100 can maintains 2-8° C. in both hot and cold ambient conditions. An example environmental range enables The top-loading portable temperature-controlled enclosure 100 to be functional across extreme temperature variations.

The top-loading portable temperature-controlled enclosure 100 includes a monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording. The top-loading portable temperature-controlled enclosure 100 can also perform automated cloud data synchronization.

The top-loading portable temperature-controlled enclosure 100 includes an Operation and Performance Temperature Performance module that manages an initial cooldown (e.g. 2 hours to reach target temperature with a temperature range: 2-8° C. maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The top-loading configuration represents a significant advancement in portable temperature-controlled storage, combining innovative solid-state cooling technology with sophisticated thermal management and monitoring systems. The design achieves exceptional efficiency and reliability while maintaining precise temperature control across varied environmental conditions.

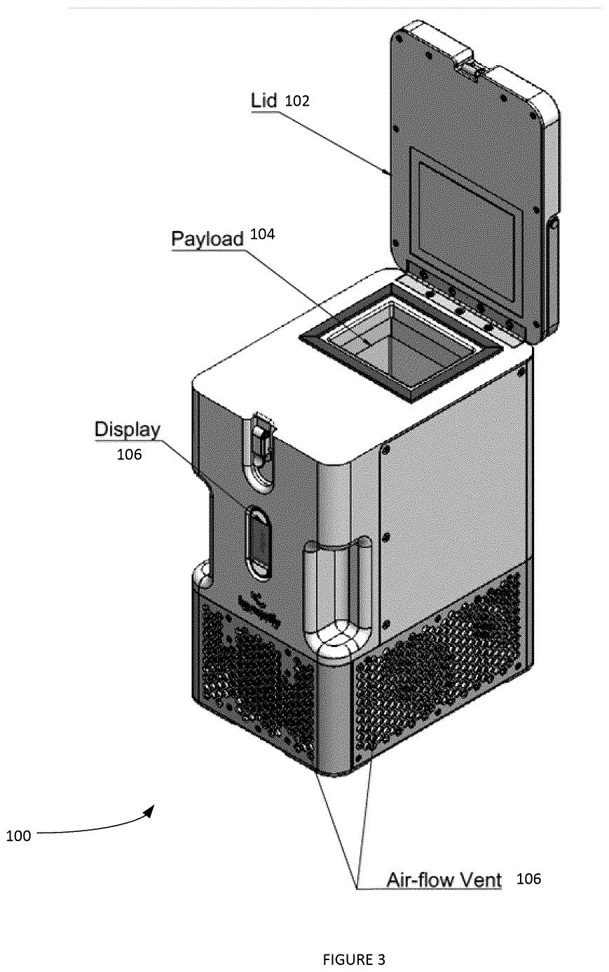

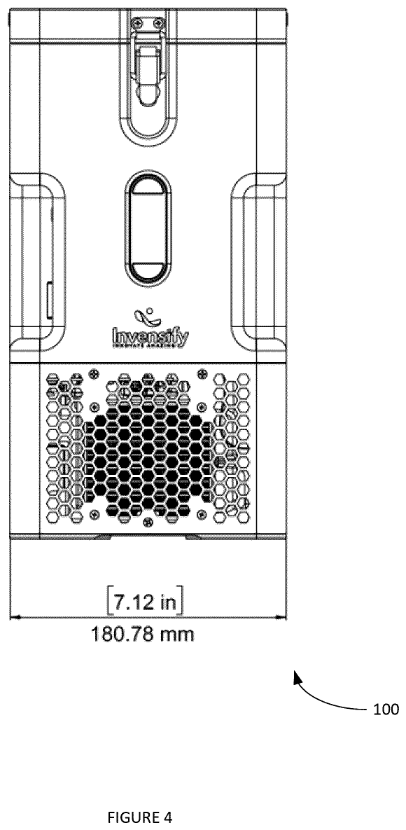

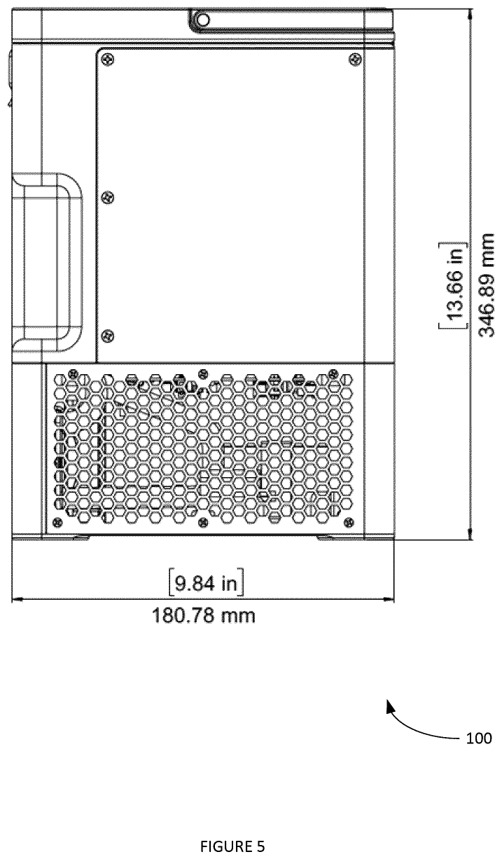

More specifically, FIG. 1 is a top view of example embodiment of a portable temperature-controlled enclosure 100, according to some embodiments. FIGS. 2 and 3 are isometric views of example embodiment of a portable temperature-controlled enclosure 100, according to some embodiments. FIG. 4 is a front view of example embodiment of a portable temperature-controlled enclosure 100, according to some embodiments. FIG. 5 is a side view of example embodiment of a portable temperature-controlled enclosure 100, according to some embodiments.

In one embodiments, portable temperature-controlled enclosure 100 can have a top-loading configuration with example payload dimensions: 3.2″×4.1″×5.5″. An example top opening capacity can be one (1) liter. Overall dimensions, by way of example, can be 107.78 mm×119.92 mm×166.84 mm. Portable temperature-controlled enclosure 100 provides a top access lid for payload (e.g. medications, etc.) insertion.

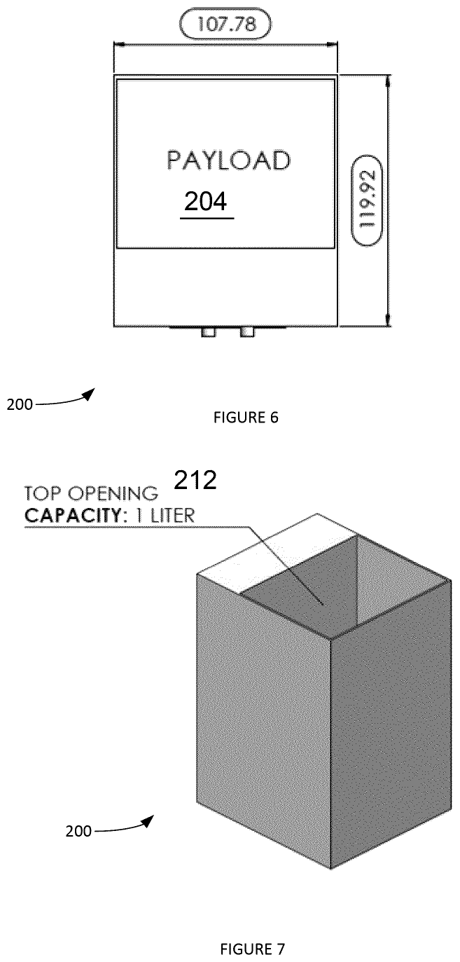

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a sophisticated thermoelectric cooling mechanism wherein electrical power is transmitted through a strategically positioned semiconductor chip 202 mounted at a calculated angular orientation relative to the aluminum payload chamber 204. The semiconductor chip 202 incorporates a material combination wherein electrons traverse between different semiconductor elements, creating an energy absorption effect at the material junction interfaces. This energy absorption phenomenon, occurring at the precise locations where the material composition transitions, facilitates the cooling process through electron mobility differentials between the semiconductor materials.

The thermal management system utilizes direct thermal coupling between the semiconductor chip 202 and an aluminum payload chamber 204, whereby the energy absorption at the material junctions actively extracts heat from the payload area through the aluminum wall interface. The extracted thermal energy is subsequently transferred to a closed-loop cooling system 206 comprising fluid-carrying pipes 208 directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214, wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demonstrably improves the speed and uniformity of temperature distribution compared to traditional perpendicular mounting arrangements.

The thermal control system can operate in a dual-power configuration, initially utilizing wall power for the cooldown phase until the target temperature (typically 2° C.) is achieved, at which point the system transitions to battery power through a lithium polymer battery assembly capable of maintaining temperature control for 72 hours of autonomous operation. The internal configuration includes various top-loading variants (e.g. via top opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber. This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

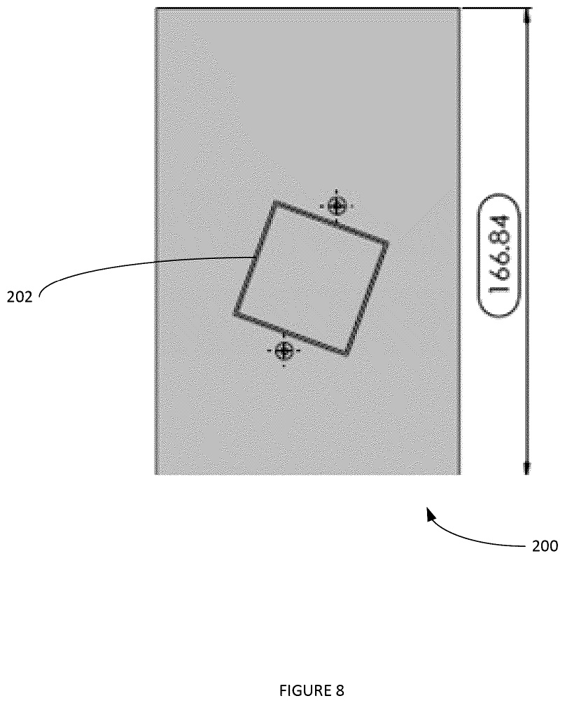

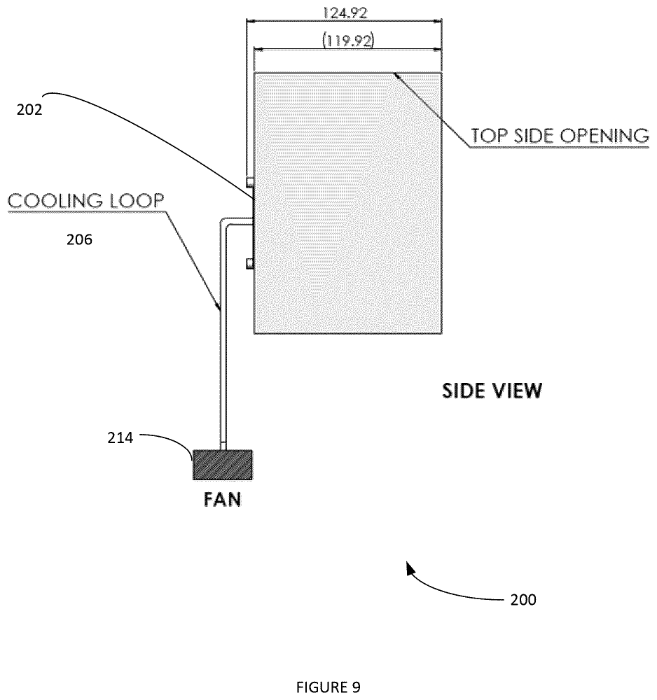

More specifically, FIG. 6 illustrates a top-view of aluminum cooling chamber portable unit 200, according to some embodiments. FIG. 7 illustrates a isometric-view of aluminum cooling chamber portable unit 200, according to some embodiments. FIG. 8 illustrates a rear-view of aluminum cooling chamber portable unit 200, according to some embodiments. FIG. 9 illustrates a side-view of aluminum cooling chamber portable unit 200, according to some embodiments.

### Example Computer Architecture and Systems

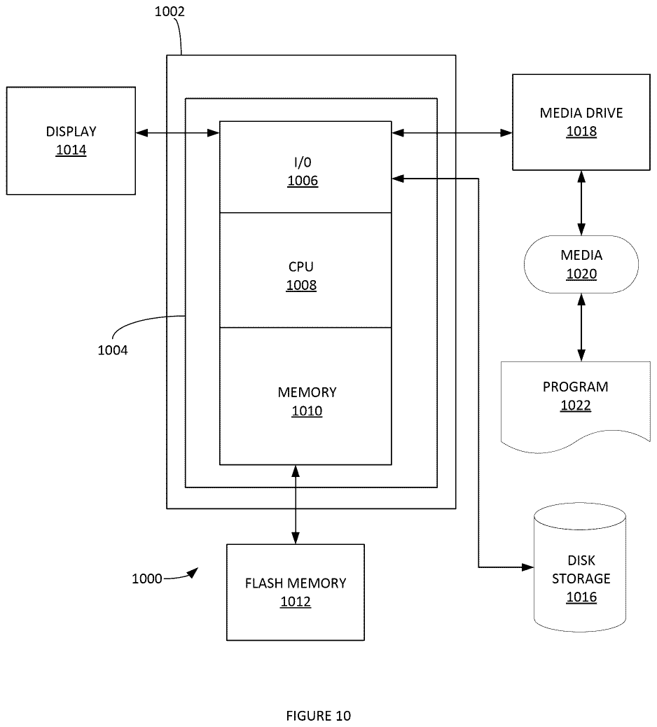

FIG. 10 depicts an exemplary computing system 1000 that can be configured to perform any one of the processes provided herein. In this context, computing system 1000 may include, for example, a processor, memory, storage, and I/O devices (e.g., monitor, keyboard, disk drive, Internet connection, etc.). However, computing system 1000 may include circuitry or other specialized hardware for carrying out some or all aspects of the processes. In some operational settings, computing system 1000 may be configured as a system that includes one or more units, each of which is configured to carry out some aspects of the processes either in software, hardware, or some combination thereof.

FIG. 10 depicts computing system 1000 with a number of components that may be used to perform any of the processes described herein. The main system 1002 includes a motherboard 1004 having an I/O section 1006, one or more central processing units (CPU) 1008, and a memory section 1010, which may have a flash memory card 1012 related to it. The I/O section 1006 can be connected to a display 1014, a keyboard and/or other user input (not shown), a disk storage unit 1016, and a media drive unit 1018. The media drive unit 1018 can read/write a computer-readable medium 1020, which can contain programs 1022 and/or data. Computing system 1000 can include a web browser. Moreover, it is noted that computing system 1000 can be configured to include additional systems in order to fulfill various functionalities. Computing system 1000 can communicate with other computing devices based on various computer communication protocols such a Wi-Fi, Bluetooth® (and/or other standards for exchanging data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, batter power, etc.) of the portable smart refrigerator. Computing system can also be coupled with various other systems such as, inter alia: temperature sensors, digital clocks, Wi-Fi systems, etc.

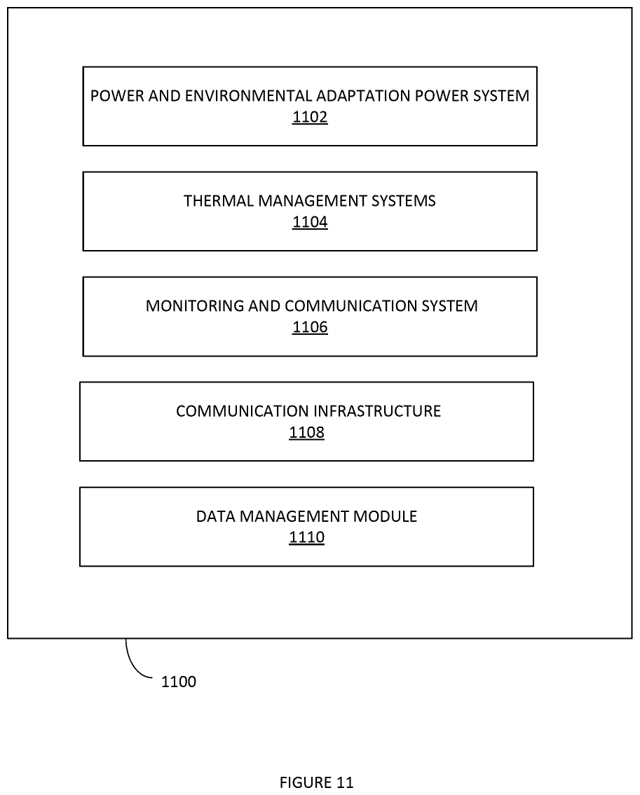

FIG. 11 illustrates a logical view 1100 of a portable temperature-controlled enclosure, according to some embodiments. Power and environmental adaptation power system 1102. The top-loading portable temperature-controlled enclosure 100 includes an input compatibility, by way of example of a Universal AC power (110V/220V) and an integrated charging system. Thermal management systems 1104 manage the temperature of top-loading portable temperature-controlled enclosure 100. Thermal management systems 110 of the top-loading portable temperature-controlled enclosure 100 can maintain 2-8° C. in both hot and cold ambient conditions. Monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording.

Additional information on chip positioning is now discussed. The innovative cooling system centers around a precisely engineered 40 mm×40 mm semiconductor chip that represents a significant advancement in portable refrigeration technology. This chip, comprising multiple semiconductor junctions arranged in an optimized pattern, is mounted at a carefully calculated 20-degree angle relative to the payload chamber wall, deviating from traditional perpendicular mounting approaches. This specific angular orientation was chosen to maximize the cooling efficiency through enhanced radial distribution patterns.

The mounting configuration creates a sophisticated thermal management system where the chip interfaces directly with the aluminum chamber wall for maximum thermal conductivity. This direct coupling is maintained by a spring-loaded mechanism that ensures a consistent 30-40 PSI mounting pressure, crucial for optimal heat transfer. The interface between the chip and wall utilizes a high thermal conductivity compound with carefully controlled thickness and verified full surface coverage.

The 20-degree mounting angle serves a critical purpose in the system's operation. Unlike conventional perpendicular mounting, which typically results in linear cooling distribution, this angular orientation creates an expanded radius of cooling influence. This radial distribution pattern enables more comprehensive coverage of the payload surface area and facilitates faster temperature equalization throughout the chamber. The result is a more efficient and effective cooling system that achieves superior thermal coverage compared to traditional mounting configurations.

In the top-loaded configuration, the chip is positioned lower, near the midsection of the wall, with the temperature sensor strategically placed inside the payload wall towards the bottom side. This positioning was specifically chosen to optimize the cooling effect in relation to the temperature sensor location. The entire setup demonstrates a carefully engineered approach to thermal management, where each component's position has been optimized for maximum efficiency.

The semiconductor chip's design and mounting create a cooling effect that disperses in a radial pattern rather than a traditional linear distribution. This radial dispersion is particularly effective because it provides more uniform coverage across the payload area. The angular mounting effectively increases the total area over which the cooling effect spreads, resulting in more efficient temperature control throughout the chamber. This innovative approach to chip mounting and cooling distribution represents a significant advancement in portable refrigeration technology, offering improved performance over conventional perpendicular mounting systems.

The system's overall design reflects a deep understanding of thermal dynamics and practical engineering considerations. By combining the precise 40 mm×40 mm chip dimensions with the 20-degree mounting angle and strategic positioning relative to temperature sensors, the system achieves optimal cooling performance while maintaining efficient use of space within the portable unit. The careful attention to mounting pressure, thermal compound application, and interface design ensures reliable and consistent performance, making this cooling system particularly well-suited for portable applications requiring precise temperature control.

### Spatio-Thermal Energy Modulation Vessel With Embedded Conductive Framework

SPATIO-THERMAL ENERGY MODULATION Cooling Chamber represents an alternative approach to thermal management through a plate-based design configuration. The system incorporates a cooling element mounted on the bottom surface rather than the traditional side-mounting approach, creating a different thermal distribution pattern.

The chamber's dimensions include a width of 10 inches (254 mm) and a length of 8.00 inches (203.20 mm), with an additional height element of 2.61 inches (66.20 mm). The design features a top opening configuration that allows for payload placement directly onto the cooling surface. This arrangement appears to optimize the thermal contact between the payload and the cooling system.

The cooling mechanism integrates both a cooling loop and a fan assembly at the bottom of the unit. This configuration suggests a design intent to create uniform cooling across the payload surface while managing heat dissipation through forced air circulation. The placement of the cooling loop beneath the payload area indicates an approach to direct thermal transfer.

The structural design incorporates two main sections: an upper payload chamber and a lower cooling system housing. The payload chamber, accessed through the top opening, provides a storage area sized to accommodate medical materials such as SPATIO-THERMAL ENERGY MODULATION cell therapy components. The lower section houses the thermal management systems, including the cooling loop and fan assembly.

The design appears suited for medical applications, particularly those involving temperature-sensitive materials like cell therapies. The layout suggests consideration for ease of access while maintaining thermal stability. The dimensional relationships between components indicate attention to heat transfer efficiency and operational practicality.

From a manufacturing perspective, the drawing includes third-angle projection views that detail the relationships between components. The design maintains consistent dimensional documentation in millimeters, supporting manufacturing standardization. The integration of the cooling system with the payload chamber suggests consideration for assembly efficiency and maintenance accessibility.

The cooling loop's position relative to the fan assembly indicates a design approach that may enhance convective heat transfer while managing system thermal loads. This configuration could support temperature uniformity across the payload surface, which can be particularly important for medical material storage applications.

The chamber's overall proportions and component layout suggest consideration for both thermal performance and user interaction. The relationship between the payload area dimensions and the cooling system components indicates attention to optimizing the balance between storage capacity and cooling capability.

In an alternative embodiment, the portable temperature-controlled enclosure 1200 can comprise an exterior housing formed as a rigid, insulated container having an approximate rectangular footprint of 12.00 inches (304.8 mm) in length and 10.00 inches (254 mm) in width, the housing being dimensioned to support handheld transport while providing sufficient interior volume for storage of temperature-sensitive payloads. The enclosure can include a hinged lid positioned along an upper surface that, when closed, forms a continuous insulated barrier and, when opened, exposes a top opening sized to permit direct placement and removal of payload materials.

A front-mounted electronic display can be integrated into the exterior wall and configured to present temperature values, battery state, operational parameters, alerts, or system-status indicators associated with internal control electronics. One or more airflow vents can be disposed along a side surface of the housing to permit air intake or exhaust associated with an internal heat-exchange subsystem, which can include forced-air movement generated by an internal fan used to manage thermal loads generated during operation of a thermoelectric-effect cooling assembly.

The insulated housing can enclose the thermoelectric-effect cooling assembly, one or more thermal control materials (TCM) positioned to moderate temperature fluctuations, control circuitry, and any battery or power-conversion hardware configured to support autonomous operation. The geometric arrangement of the lid, display, vent structures, and the defined top opening can provide an enclosure configuration that supports ergonomic access to the payload area while maintaining the thermal performance characteristics required for medical, biological, or industrial payloads. This embodiment represents an alternative enclosure architecture while utilizing the same thermoelectric-effect cooling principles, thermal control materials (TCM), monitoring and communication subsystems, and power-management techniques disclosed for the previously described portable refrigerator system.

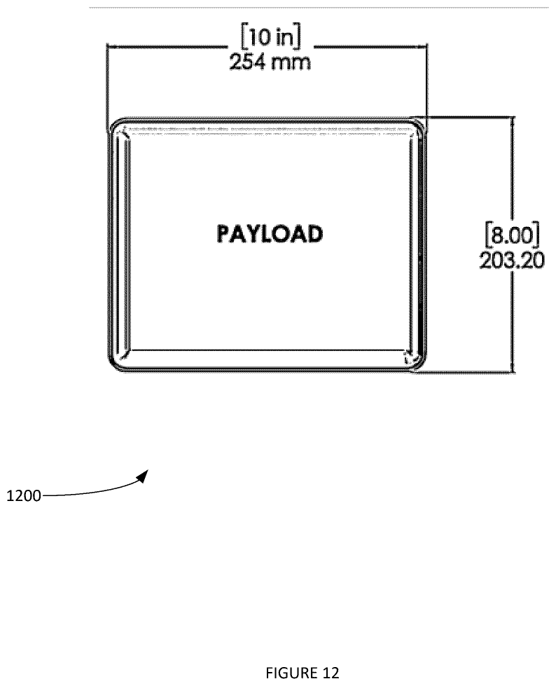

FIG. 12 illustrates an exterior view of portable temperature-controlled enclosure 1200 having a rectangular insulated housing configured for top-loading operation, according to some embodiments. A hinged lid is positioned along the upper surface, a display region is provided on the front face for presenting temperature or system-status information, and a ventilation opening is located on a lateral surface to support airflow routed through internal heat-exchange components. Portable temperature-controlled enclosure 1200 has an approximate footprint of 12.00 inches by 10.00 inches and encloses, within its insulated structure, a thermoelectric-effect cooling assembly, thermal control materials (TCM), control electronics, temperature monitoring circuitry, communication hardware, and power-management components configured to support temperature regulation, data logging, alert signaling, and autonomous operation. Although these internal subsystems are not visible in FIG. 12, they operate in conjunction with the thermoelectric-effect assembly to maintain a defined temperature range within the payload region. The exterior configuration shown in FIG. 12 provides an alternative enclosure architecture that supports the same solid-state cooling principles, thermal-buffering strategies, and monitoring capabilities described for earlier embodiments.

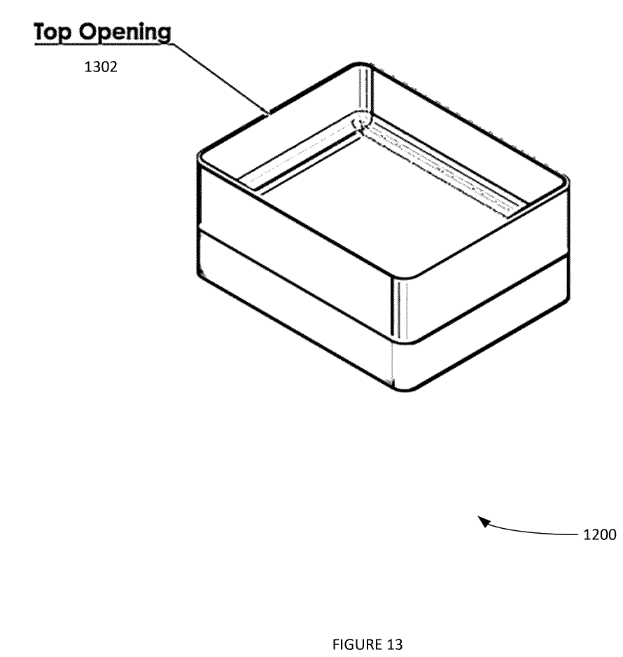

FIG. 13 provides a top view of portable temperature-controlled enclosure 1200. This view shows the external perimeter of the insulated housing and the top opening 1302, which becomes accessible when the hinged lid is raised. Top opening 1302 forms the entry region for placement of payload materials into the internal storage cavity, which includes temperature sensors, thermal mass regions, airflow pathways, and interior-facing structures that are not shown in the figure. The relative proportions of the enclosure footprint and top opening 1302 demonstrate the enlarged access area provided by this alternative housing configuration. This broader ingress region is consistent with a system that supports stable placement of medical or industrial payloads, integration with thermoelectric-effect cooling mechanisms, and the TCM-based thermal buffering described elsewhere in the specification.

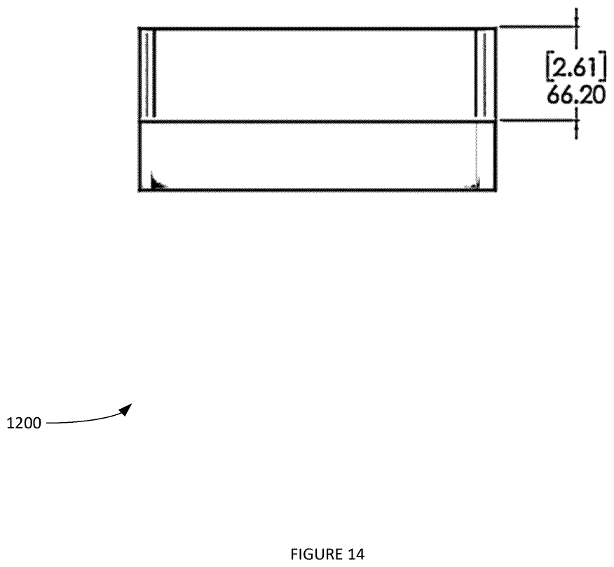

FIG. 14 provides a front view of portable temperature-controlled enclosure 1200, according to some embodiments. The forward-facing display surface presents temperature values, operational indicators, battery status, alerts, and system-state information generated by internal control electronics and monitoring circuitry positioned within the insulated housing. Although hidden in this view, the interior of portable temperature-controlled enclosure 1200 includes the thermoelectric-effect cooling module, thermal spreaders, TCM regions, data logging systems, communication modules, and support electronics. The front view highlights the frontal geometry of the enclosure, including the height and width of the outer shell and the location of user-interface elements that facilitate real-time monitoring during autonomous and externally powered operation.

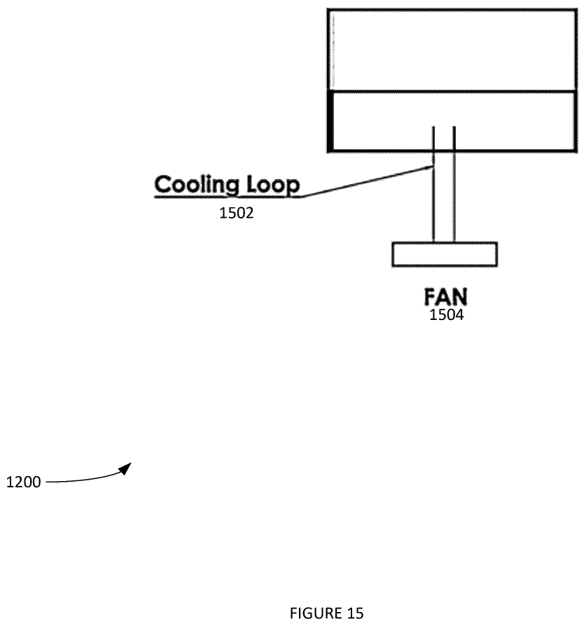

FIG. 15 provides a side view of portable temperature-controlled enclosure 1200, according to some embodiments. This view illustrates ventilation opening 1502 along a lateral surface of the insulated housing and the lower boundary 1504 forming the underside of the enclosure. Ventilation opening 1502 is configured to permit intake or exhaust airflow driven by internal heat-exchange components, including forced-air structures, heat-dissipation elements, and cooling-path arrangements that are not visible in the figure. These internal subsystems operate in conjunction with the thermoelectric-effect cooling module and thermal control materials (TCM) housed within the enclosure to expel waste heat during initialization, steady-state maintenance, or cooldown cycles. The lateral geometry shown in FIG. 15 demonstrates the external airflow routing strategy and enclosure form factor used to support the overall thermal-management architecture while preserving compatibility with the operational modes described for earlier embodiments.

Portable temperature-controlled enclosure 1200 represents an alternative enclosure architecture that provides a distinct physical configuration while operating on the same thermoelectric-effect cooling principles, thermal control material (TCM) buffering strategies, monitoring systems, and power-management designs disclosed for earlier embodiments. Portable temperature-controlled enclosure 1200 is formed as a larger rectangular insulated housing with an approximate footprint of 12.00 inches (304.8 mm) in length and 10.00 inches (254 mm) in width, thereby enabling increased internal storage volume, alternative component layout, and enhanced thermal subsystem distribution compared to the smaller top-loading enclosure previously described.

Portable temperature-controlled enclosure 1200 includes a full-width hinged lid positioned along an upper surface of the housing. When closed, the hinged lid forms a continuous insulated boundary that supports thermal retention during autonomous operation. When opened, the lid exposes a top-opening access region sized to permit placement of payload items directly into the storage cavity of portable temperature-controlled enclosure 1200. The enlarged rectangular top opening supports broader payload geometries than the earlier embodiment and may facilitate loading of horizontally oriented materials, medical supplies, instruments, or other temperature-sensitive items requiring direct access through a widened upper aperture.

The exterior housing of portable temperature-controlled enclosure 1200 integrates a front-mounted electronic display coupled to the internal computing and control system. The display is mounted directly into the exterior shell and provides temperature values, battery indicators, alerts, operational states, and other system parameters during use. This integrated display interface on the front surface distinguishes portable temperature-controlled enclosure 1200 from previously disclosed embodiments wherein such user interfaces were represented only as functional diagrams rather than as physically incorporated structural elements.

Portable temperature-controlled enclosure 1200 further includes one or more airflow vents positioned along a side wall of the insulated housing. The vent structure is configured to support intake or exhaust airflow associated with a heat-exchange subsystem operating in conjunction with the thermoelectric-effect cooling elements. The placement and geometry of the side-mounted airflow vent enable forced-air circulation for dissipating waste heat generated during cooling cycles, creating a defined convection pathway within a compact insulated housing. This side-vent arrangement represents a structural distinction from the earlier enclosure embodiment, providing an improved thermal exhaust interface and facilitating alternative internal heat-exchanger positioning.

The increased housing dimensions of portable temperature-controlled enclosure 1200 inherently enable alternative internal component distribution. The enlarged interior volume supports different arrangements of the thermoelectric-effect cooling assembly, thermal control material (TCM) modules, battery assemblies, control boards, and mechanical supports. Portable temperature-controlled enclosure 1200 can accommodate increased TCM mass, expanded battery capacity, or revised thermal spreading structures positioned within the insulated boundaries of the enclosure. This expanded internal architecture allows portable temperature-controlled enclosure 1200 to maintain prolonged operation under variable ambient conditions, offering enhanced endurance relative to smaller footprints.

Portable temperature-controlled enclosure 1200 provides a multi-surface user-interaction design, including a top-loading interface through the hinged lid, a front-facing display interface, and a side-surface thermal management interface through the airflow vent. The combination of these three functional surfaces—top, front, and lateral—creates a distinct ergonomic and operational layout. The positioning and interaction of these external components enable portable temperature-controlled enclosure 1200 to support improved accessibility, simplified payload insertion, and more effective heat management compared to previous configurations.

The insulated outer shell of portable temperature-controlled enclosure 1200 incorporates a flatter and broader geometric profile that differs from the more compact vertical configuration of earlier embodiments. This structure may support different manufacturing approaches, such as multi-part injection molding, modular insulation panel insertion, or integrated display and vent cutout tooling. The revised outer-shell architecture provides opportunities for assembly efficiencies, maintenance accessibility, and expanded internal component placement without altering the core cooling principles of the system.

Portable temperature-controlled enclosure 1200 therefore introduces a set of structural and functional improvements, including an enlarged rectangular footprint, an integrated front-mounted display, a side-mounted airflow vent geometry, a full-width hinged lid with expanded top-loading access, increased TCM and battery capacity, and a redistributed thermoelectric-effect cooling assembly. These features collectively differentiate portable temperature-controlled enclosure 1200 as a distinct enclosure embodiment while maintaining operational compatibility with the solid-state cooling, thermal buffering, power-management, and monitoring systems previously disclosed.

In certain embodiments, the payload chamber further comprises an internal thermal-spreader plate formed from a high-conductivity alloy (e.g., 1100-grade aluminum or copper-aluminum composite) having a thickness between 1.0 mm and 6.0 mm. The thermal-spreader plate is mechanically bonded to the upper surface of the thermoelectric cooling assembly using a compressive interface material (TIM) exhibiting a thermal conductivity of at least 4.0 W/m·K. This structure is configured to reduce localized cold spots and generate uniform planar isotherms across at least 85% of the payload contact surface.

The system can further incorporate a stratification suppression module comprising one or more low-profile micro-channel airflow tunnels positioned beneath the thermal control material (TCM) regions. These channels can be dimensioned between 0.5 mm and 2.0 mm in height and are configured to disrupt vertical thermal gradients in the payload chamber during extended autonomous operation.

In some embodiments, the temperature-control loop includes dual redundant temperature-sensing elements positioned at different vertical heights within the storage cavity. A supervisory microcontroller can calculate ΔTz (temperature differential along the vertical axis) and dynamically adjust fan drive duty cycles, compressor/Peltier current delivery, or both, to maintain ΔTz within ±0.4°C.

The enclosure can further include a multilayer electromagnetic interference (EMI) shielding structure comprising an internal grounded metallic foil barrier placed between the battery module and the control electronics. The EMI shield prevents frequency-induced deviation in thermoelectric driver current and preserves temperature measurement accuracy within ±0.1°C under external RF exposure conditions up to 6 GHz.

In certain embodiments, the control firmware utilizes a predictive PID regulation model incorporating thermal mass estimation based on the size and heat capacity of the stored payload. The controller measures the initial temperature drop slope over a defined interval and mathematically infers payload thermal inertia to dynamically adjust the setpoint approach rate, thereby minimizing overshoot.

The battery management subsystem can include a dual-rail power delivery bus that transitions between (i) a high-efficiency 24-V buck mode for active cooldown and (ii) a low-energy 12-V sustainment mode during steady-state hold periods. This dual-mode configuration can reduce total power draw by 20-45% while maintaining thermal compliance.

In some embodiments, the cooling chamber includes a modular payload insert fabricated from vacuum-formed polymer or CNC-machined material. The insert geometry can be altered to conform to vial racks, plasma pouches, cryobags, or autologous CAR-T therapy cassettes while preserving thermal contact with the upper cooling surface.

A distributed thermal integrity verification process can be executed periodically during operation, wherein the control electronics inject a brief, controlled thermal impulse into the cooling plate and simultaneously measure response profiles via multiple sensors. Deviation from a known thermal diffusion signature can indicate partial refrigerant blockage, thermal paste failure, or payload mis-seating, enabling predictive maintenance alerts.

Some embodiments include a passive thermal-ballast region formed from phase-change material (TCM) positioned along at least one internal wall surface of the insulated housing. The TCM is selected to undergo phase transition within ±1° C. of the system setpoint temperature, thereby buffering thermal transients and extending autonomous hold time during unexpected power loss.

The payload enclosure geometry illustrated in FIGS. 12-15 may further include an internal rib structure formed from injection-molded polymer or stamped aluminum. The rib structure increases mechanical resistance to deformation under strap load while also providing a thermal conduction pathway to dissipate localized heat generated by control electronics positioned in the lower chamber.

In alternative embodiments, the enclosure may be configured to enter a failsafe low-power mode in response to sensor-detected internal temperature rise exceeding 2.0° C. beyond the programmed threshold. The system can automatically disable non-essential subsystems, activate emergency fan override, and transmit wireless alerts via Bluetooth LE, LTE-M, or LoRaWAN communication modules.

The airflow vent shown in the side-elevation drawing may incorporate an internal baffle array configured to prevent foreign object ingress while maintaining airflow impedance below 0.05 in H₂O at nominal fan speeds. The baffle structure may be formed as a removable, injection-molded component that enables periodic cleaning, thereby extending heat-exchanger performance life. The combined arrangement of (i) bottom-mounted conductive cooling architecture, (ii) multi-axis thermal stratification suppression, and (iii) autonomous dual-rail power regulation has not been previously disclosed in any portable medical cooling enclosure, and provides continuous payload temperature integrity under variable external thermal loads.

### Conclusion

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

What is claimed by United States Patent:

1. A portable temperature-controlled enclosure comprising:
a thermally insulated housing defining an interior payload chamber;
a thermoelectric-effect cooling assembly thermally coupled to the payload chamber through a thermal interface material applied at a controlled thickness and verified for full-surface coverage;
a thermal control material positioned adjacent to the payload chamber to provide thermal buffering and lateral heat spreading;
a heat-exchange subsystem configured to dissipate heat generated by the thermoelectric-effect cooling assembly;
a power subsystem comprising a rechargeable battery configured to operate the thermoelectric-effect cooling assembly in an autonomous mode; and
a control system comprising one or more temperature sensors and electronics configured to regulate the thermoelectric-effect cooling assembly to maintain the payload chamber within a defined temperature range.

2. The portable temperature-controlled enclosure of claim 1, wherein the thermoelectric-effect cooling assembly is mounted under a defined mounting pressure to maintain consistent thermal coupling.

3. The portable temperature-controlled enclosure of claim 2, wherein the thermoelectric-effect cooling assembly comprises a semiconductor module having dimensions of approximately 40 mm by 40 mm.

4. The portable temperature-controlled enclosure of claim 1, wherein the payload chamber is dimensioned to accommodate a payload volume of approximately one liter.

5. The portable temperature-controlled enclosure of claim 1, wherein the interior of the housing comprises an upper payload region and a lower cooling-assembly region separated by an internal structural division.

6. The portable temperature-controlled enclosure of claim 1,
wherein the thermoelectric-effect cooling assembly is mounted at a selected angular orientation relative to a wall of the payload chamber to enhance radial thermal distribution,
wherein the heat-exchange subsystem comprises a forced-air ventilation pathway routed through at least one opening in the housing,
wherein the thermal control material is arranged in a geometric configuration positioned to stabilize temperature across lateral surfaces of the payload chamber,
wherein the control system further comprises data-logging electronics configured to record temperature information during autonomous operation, and
wherein the thermoelectric-effect cooling assembly is positioned within the lower cooling-assembly region while the payload is supported within the upper payload region.

7. The portable temperature-controlled enclosure of claim 1, wherein the control system is configured to calculate a payload thermal-mass estimate based on measured cooldown slope and adjust thermoelectric drive current according to a predictive temperature-regulation algorithm.

8. The portable temperature-controlled enclosure of claim 1, wherein the control system further comprises dual redundant temperature sensors positioned at different vertical elevations within the payload chamber and configured to maintain a vertical thermal gradient below ±0.4 ° C. during operation.

9. The portable temperature-controlled enclosure of claim 1, wherein the power subsystem comprises a dual-voltage power bus configured to operate the thermoelectric-effect cooling assembly at a first voltage during cooldown and a reduced second voltage during steady-state regulation to reduce total energy consumption.

10. The portable temperature-controlled enclosure of claim 1, wherein the thermal control material is positioned in a stratification-suppression arrangement comprising one or more low-profile micro-channel air gaps dimensioned between 0.5 mm and 2.0 mm to disrupt vertical thermal gradients.

11. The portable temperature-controlled enclosure of claim 1, further comprising an electromagnetic interference (EMI) shielding layer positioned between the battery subsystem and the control system to prevent RF-induced deviation in temperature sensing accuracy.

12. The portable temperature-controlled enclosure of claim 1, wherein the control system is further configured to execute a thermal-integrity verification cycle comprising injection of a controlled heat impulse and measurement of thermal diffusion signatures to detect payload mis-seating or thermal-interface degradation.

13. The portable temperature-controlled enclosure of claim 1, wherein the thermoelectric-effect cooling assembly is mounted under a calibrated compressive load selected to maintain thermal contact pressure between 40 kPa and 120 kPa.

14. The portable temperature-controlled enclosure of claim 1, wherein the heat-exchange subsystem comprises a removable baffle structure configured to maintain airflow impedance below 0.05 in H₂O at nominal fan speeds while preventing particulate ingress.

15. The portable temperature-controlled enclosure of claim 1, wherein the enclosure is configured to enter a failsafe low-power mode when internal temperature rises more than 2 ° C. beyond a defined setpoint, the failsafe mode comprising automatic shutdown of non-essential electronics, forced-fan override, and wireless alert transmission.

16. The portable temperature-controlled enclosure of claim 1, wherein the control system comprises firmware configured to dynamically transition between a closed-loop PID control mode and an open-loop energy conservation mode according to predicted ambient thermal load.

17. The portable temperature-controlled enclosure of claim 1, wherein the payload chamber floor comprises a thermally conductive plate having a thermal conductivity of at least 180 W/m·K and a thickness between 1 mm and 6 mm,
wherein the battery subsystem is configured to sustain temperature regulation for at least 72 hours under ambient temperatures between 20 ° C. and 30 ° C.,
wherein the housing further comprises internal reinforcement ribs configured to maintain dimensional stability under mechanical vibration exceeding 3 G,
wherein the thermoelectric-effect cooling assembly and thermal control material operate cooperatively in a hybrid mode that increases temperature hold duration by at least 25% relative to active cooling alone, and
wherein the control system further comprises an adaptive power-allocation algorithm configured to proportionally reduce thermoelectric drive current as remaining battery capacity decreases, thereby extending thermal regulation duration without exceeding a ±1 ° C. deviation from setpoint.

18. The portable temperature-controlled enclosure of claim 1, further comprising a modular payload insert configured to receive medical vials, cryobags, cell-therapy cassettes, or blood components while maintaining conductive contact with the cooling surface.

19. A portable temperature-controlled enclosure comprising a thermally insulated housing having an external footprint measuring approximately 12.00 inches by 10.00 inches and enclosing a payload chamber having internal dimensions of approximately 10 inches in width, 8 inches in length, and 2.61 inches in height, the payload chamber comprising a rectangular geometry and a plate-style lower surface configured to receive direct thermal conduction from a cooling assembly, the payload chamber further including a top-loading access opening sized to permit placement of temperature-sensitive materials; a thermoelectric-effect cooling assembly positioned beneath the plate-style lower surface and thermally coupled to the payload chamber through a thermal interface material applied at a controlled thickness and verified for full-surface coverage; a thermal control material positioned adjacent to lateral surfaces of the payload chamber to provide passive thermal buffering and lateral heat spreading; a structural separation between the payload chamber defined by said dimensions and a lower cooling-assembly region housing the thermoelectric-effect cooling assembly; a heat-exchange subsystem configured to dissipate heat generated by the thermoelectric-effect cooling assembly through at least one ventilation opening in the housing; a rechargeable battery configured to power the thermoelectric-effect cooling assembly during autonomous operation; and a control system comprising one or more temperature sensors positioned to detect temperature within the payload chamber and electronics configured to regulate operation of the thermoelectric-effect cooling assembly to maintain the payload chamber within a defined temperature range.

20. A method of maintaining a medical payload at a controlled temperature within a portable temperature-controlled enclosure, the method comprising:
(a) sensing temperature at two or more vertical elevations within an interior payload chamber defined by a thermally insulated housing, the sensing performed using temperature sensors operatively coupled to a control system;
(b) receiving, by the control system, temperature data from the two or more temperature sensors and computing a real-time payload thermal-mass estimate based at least on an observed initial cooldown slope within the payload chamber;
(c) regulating thermoelectric drive current supplied to a thermoelectric-effect cooling assembly thermally coupled to the payload chamber through a thermal interface material applied at a controlled thickness and verified for full-surface coverage, the regulating performed according to a predictive temperature-regulation model that adjusts cooling output based on the computed thermal-mass estimate;
(d) determining, by the control system, a vertical thermal-gradient value (ΔTz) and selectively activating a heat-exchange subsystem comprising a forced-air ventilation pathway when the vertical thermal-gradient value exceeds a defined threshold, thereby dissipating heat generated by the thermoelectric-effect cooling assembly;
(e) autonomously adjusting power delivery to the thermoelectric-effect cooling assembly according to remaining battery capacity by transitioning between a first voltage level for cooldown operation and a reduced second voltage level for steady-state temperature regulation; and
(f) maintaining, through cooperative operation of the thermoelectric-effect cooling assembly and a thermal control material positioned adjacent to the payload chamber, the interior payload chamber within a defined temperature range suitable for preserving the stability of the medical payload.
